(19) United States
(12) Patent Application Publication
(10) Pub. No.: US 2017/0069782 A1
(43) Pub. Date: Mar. 9, 2017

(54) Four-Junction Solar Cell and Fabrication Method

(71) Applicant: XIAMEN SANAN OPTOELECTRONICS TECHNOLOGY CO., LTD., Xiamen (CN)

(72) Inventors: Minghui SONG, Xiamen (CN); Guijiang LIN, Xiamen (CN); Wenjun CHEN, Xiamen (CN); Jingfeng BI, Xiamen (CN); Guanzhou LIU, Xiamen (CN); Meijia YANG, Xiamen (CN); Mingyang LI, Xiamen (CN)

(73) Assignee: XIAMEN SANAN OPTOELECTRONICS TECHNOLOGY CO., LTD., Xiamen (CN)

(21) Appl. No.: 15/356,709

(22) Filed: Nov. 21, 2016

Related U.S. Application Data
(63) Continuation of application No. PCT/CN2014/094877, filed on Dec. 25, 2014.

(30) Foreign Application Priority Data
Jun. 24, 2014 (CN) 201410285057.0

(51) Int. Cl. H01L 31/18; H01L 31/0203; H01L 31/0296

(52) U.S. Cl. CPC H01L 31/1844; H01L 31/1852; H01L 31/02966; H01L 31/0203

(57) ABSTRACT

A method of fabricating a four-junction solar cell includes: forming a first epitaxial structure comprising first and second subcells and a cover layer over a first substrate through a forward epitaxial growth, and forming a second epitaxial structure comprising third and fourth subcells over the second substrate; forming a groove and a metal bonding layer; forming a groove on the cover layer surface of the first epitaxial structure and the substrate back surface of the second epitaxial structure, and depositing a metal bonding layer in the groove; and bonding the first epitaxial structure and the second epitaxial structure; bonding the cover layer surface of the first epitaxial structure and the substrate back surface of the second epitaxial structure, ensuring that the metal bonding layers are aligned to each other to realize dual bonding between the metal bonding layers and between the semiconductors through high temperature and high pressure treatment.

### CROSS-REFERENCE TO RELATED APPLICATIONS

The present application is a continuation of, and claims priority to, PCT/CN2014/094877 filed on Dec. 25, 2014, which claims priority to Chinese Patent Application No. CN 201410285057.0 filed on Jun. 24, 2014. The disclosures of these applications are hereby incorporated by reference in their entirety.

### BACKGROUND

In recent years, wide concerns have been paid to the development and use of solar energy and photovoltaic technology. Thanks to high conversion efficiency and cost cutting, compound semiconductor solar cell is recognized as one of the most potential power generation technologies for ground application.

With continuous study and search, people have developed several types of compound solar cell structures to get high conversion efficiency, including double-junction and three junction solar cell, amorphous structure, flip-chip structure, etc. For example, Emcore Company has reported a flip-chip epitaxial technology to successfully form a four-junction solar cell of GaInP/GaAs/InGaAs(1.0 eV)/InGaAs(0.7 eV) through one-time epitaxy on the GaAs substrate. In general, in use of flip-chip epitaxial technology, at first, grow the thin emitter layer; and then grow the thick base and other subcell structures. Due to emitter layer annealing, the top cell structure will change (in thickness, doping and interface) during this long growth process, making the entire structure difficult to be controlled and greatly influencing the cell performance.

Another way to get the four junction cell is to bond two dual-junction cells through wafer bonding. This technology method has low requirements on epitaxial technology, and the key is to develop wafer bonding technology. In general, wafer bonding technology is divided into direct semiconductor bonding, alignment bonding and medium insert bonding. Direct semiconductor bonding is to form a covalent bond between semiconductors through high temperature and high pressure. To get good bond strength, the crystal orientations at the semiconductor bonding interface should be aligned to each other, which is difficult to achieve. Medium insert bonding has high requirements on bonding medium, like high conductivity and translucency. Therefore, medium selection is important. Soitec has developed a GaInP/GaAs/InGaAsP/InGaAs four-junction cell with ITO as the bonding medium. However, ITO only has about 85% translucency for long-wavelength light (>1,000 nm), resulting in current limit of dual-junction cell at bottom and low cell performance. Alignment bonding process is to make metal grid lines at two bonding interfaces and align the metal grid lines. This method delivers qualified bonding strength. However, due to certain thickness of the metal grid lines, after bonding, the semiconductor interface has one layer of gap, which is disadvantageous to product application. In general, the gap is only hundreds of nanometers thick, making it very difficult to be filled.

### SUMMARY

The present disclosure provides a high-efficient four-junction solar cell and fabrication method. With normal epitaxial technology, a dual bonding process is used between the bonding metals and between the semiconductors, thus removing the problems of insufficient bonding strength in direct semiconductor bonding and gap problem in alignment bonding.

A high-efficient four-junction solar cell comprises: a first epitaxial structure and a second epitaxial structure above, wherein, the first epitaxial structure comprises a first substrate, a first subcell, a second subcell and a cover layer stacked from bottom to up, and the second epitaxial structure comprises a second substrate, a third subcell and a fourth subcell stacked from bottom to up; the cover layer surface of the first epitaxial structure and the second substrate back surface of the second epitaxial structure have a groove deposited with a metal bonding layer; the cover layer surface of the first epitaxial structure and the second substrate back surface of the second epitaxial structure are bonded, and the bonding surface is divided into a groove region and an another region, in which, the groove region is the region where the groove locates and the bonding interface between the metal bonding layers, and the another region is the bonding interface between the cover layer and the second substrate.

The bonding interface between the metal bonding layers and the bonding interface between the cover layer and the second substrate are vertically (at the epitaxial growth direction of the epitaxial structure) projected to each other and not overlapped.

A fabrication method of four-junction solar cell, comprises: forming a first epitaxial structure and a second epitaxial structure through epitaxial growth; forming a first epitaxial structure on a first substrate through normal epitaxial technology, and forming a second epitaxial structure on the second substrate, where, the first epitaxial structure comprises a first subcell, a second subcell and a cover layer formed on the first substrate; the second epitaxial structure comprises a third subcell and a fourth subcell on the second substrate; forming a groove and a metal bonding layer; forming a groove on the cover layer surface of the first epitaxial structure and the substrate back surface of the second epitaxial structure, and depositing a metal bonding layer in the groove; and bonding the first epitaxial structure and the second epitaxial structure; bonding the cover layer surface of the first epitaxial structure and the substrate back surface of the second epitaxial structure, ensuring that the metal bonding layers are aligned to each other to realize dual bonding between the metal bonding layers and between the semiconductors through high temperature and high pressure treatment, thus fabricating a high-efficient four-junction solar cell.

Preferable, the first substrate is a Ge substrate, and the second subcell is composed of an InGaAs emitter layer and a base.

Preferable, the cover layer of the first epitaxial structure can be GaAs, InGaP or InGaAs.

Preferable, the second substrate is a GaAs substrate; the third subcell is composed of an InGaAsP or AlInGaAs emitter layer and a base; and the fourth subcell is composed of an AlInGaP emitter layer and a base.

Preferable, the metal bonding layer is made of AuGe alloy, AuSn alloy, AuBe alloy, Au or their combinations.

Preferable, the metal bonding layer takes up 1‰-10% of the first and the second epitaxial structures.

Preferable, relationship between height of the metal bonding layer H and depth of the groove D is: 0<H-D<300 nm.

At least some embodiments of the present disclosure can have one or more of the following advantages: normal epitaxial technology delivers a simple way to fabricate four-junction subcells with high quality and guaranteed performance. Besides, dual bonding process is used between the bonding metals and between the semiconductors, thus removing the problems of insufficient bonding strength in direct semiconductor bonding and gap problem in alignment bonding.

Other features and advantages of this present disclosure will be described in detail in the following specification, and it is believed that such features and advantages will become more obvious in the specification or through implementations of this invention. The purposes and other advantages of the present disclosure can be realized and obtained in the structures specifically described in the specifications, claims and drawings.

### BRIEF DESCRIPTION OF THE DRAWINGS

The accompanying drawings, which are included to provide a further understanding of the invention and constitute a part of this specification, together with the embodiments, are therefore to be considered in all respects as illustrative and not restrictive. In addition, the drawings are merely illustrative, which are not drawn to scale.

FIG. 1 is a side sectional view of a four-junction solar cell in accordance with the present invention.

FIG. 2 is a side sectional view of a first epitaxial structure grown on the Ge substrate.

FIG. 3 is a side sectional view of a second epitaxial structure grown on the GaAs substrate.

FIG. 4 is a side sectional view where a groove is formed on the cover layer surface of the first epitaxial structure and the substrate back surface of the second epitaxial structure, and a metal bonding layer is deposited in the groove.

FIG. 5 illustrates a first bonding interface pattern for the four-junction solar cell of FIG. 1.

FIG. 6 illustrates a second bonding interface pattern for the four-junction solar cell of FIG. 1.

FIG. 7 illustrates a third bonding interface pattern for the four-junction solar cell of FIG. 1.

FIG. 8 illustrates a fourth bonding interface pattern for the four-junction solar cell of FIG. 1.

FIG. 9 is a side sectional view of an AlInGaP/InGaAsP/InGaAs/Ge four-junction solar cell according to some embodiments.

### DETAILED DESCRIPTION

Details of the invention, including the demonstrations and embodiments, will be described below. Refer to diagrams and descriptions below, where same reference numbers are used to identify elements with same or similar functions, with the intention to describe main characteristics of exemplary embodiments through simple diagrams.

The embodiments below disclose a high-efficient four-junction solar cell and fabrication method: form a first epitaxial structure on a Ge substrate through normal epitaxial technology, and form a second epitaxial structure on a GaAs substrate, where, the first epitaxial structure comprises a first Ge subcell, a second InGaAs subcell and a cover layer formed on the Ge substrate; the second epitaxial structure comprises a tunnel junction, a third subcell and a fourth subcell on the GaAs substrate; open a groove on the substrate back surface of the second epitaxial structure and the surface of the first epitaxial structure through normal chip process; deposit a metal bonding layer in the groove, where the metal layer thickness is larger than the groove depth with height difference within 300 nm; bond the surface of the first epitaxial structure and the substrate back surface of the second epitaxial structure, ensuring that the metal bonding layers are aligned to each other to realize dual bonding between the metal bonding layers and between the semiconductors through high temperature and high pressure treatment, thus fabricating a high-efficient four-junction solar cell.

Referring to FIG. 1, a four-junction solar cell, comprises a first epitaxial structure 100 and a second epitaxial structure 200, where, the first epitaxial structure 100 comprises a p-type Ge substrate 101, an n-type Ga_{0.5}In_{0.5}P window layer 111, an n++-GaAs/p++-GaAs tunnel junction 120, a p-type InGaAs stress gradient layer 130, a second subcell 140 and a cover layer 150; and the second epitaxial structure 200 comprises an n-type GaAs substrate 201, an n++-GaInP/p++-AlGaAs tunnel junction 210, a third subcell 220, an n++-GaInP/p++-AlGaAs tunnel junction 230 and a fourth subcell 240. The cover layer 150 surface of the first epitaxial structure 100 and the back surface of the n-type GaAs substrate 201 of the second epitaxial structure 200 have a groove, deposited with a metal bonding layer 310; the cover layer surface of the first epitaxial structure and the second substrate back surface of the second epitaxial structure are bonded, and the bonding surface 300 is divided into a groove region 310 and an another region 320, where the groove region 310 is the bonding interface between metal bonding layers, and the another region 320 is the bonding interface between the cover layer 150 and the second substrate 201.

Details will be given to the above four-junction solar cell structure in combination with fabrication method.

A fabrication method of four-junction solar cell comprises steps below:

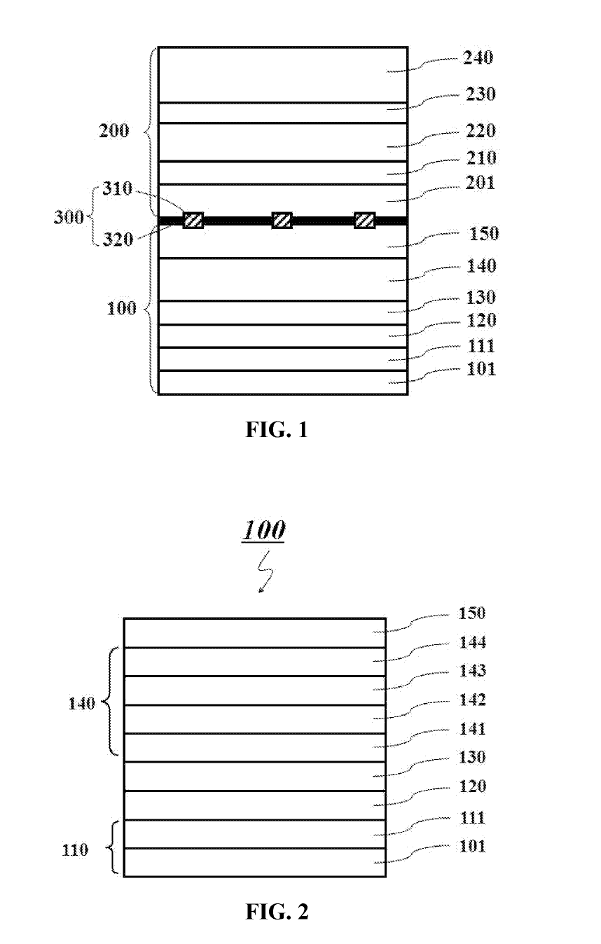

Through epitaxial growth, form a first epitaxial structure 100. Clean the p-type Ge substrate 101 and put it into a MOCVD reaction chamber, where the chamber pressure is set at 120 mbar. At first, bake the substrate for 10 minutes under 750° C., and lower the temperature to 600° C.; through epitaxial growth, form an n-type Ga_{0.5}In_{0.5}P window layer 111 with growth rate of 1 ∪/s and doping concentration of 5×10¹⁸ cm⁻³, and form a first Ge subcell 110. On the first Ge subcell 110, form an n++-GaAs/p++-GaAs tunnel junction 120 through epitaxial growth, and lower the temperature to 580° C. At first, grow an n-type GaAs layer with growth thickness of 15 nm and doping concentration of 2×10¹⁹ cm⁻³, and then grow a p-type GaAs layer with growth thickness of 15 nm and doping concentration of 2×10²⁰ cm⁻³. On the n++-GaAs/p++-GaAs tunnel junction 120, form a p-type InGaAs stress gradient layer 130 through epitaxial growth, and keep the TMGa flow constant to make the In components gradually change from 0 to 0.23 through step gradient. About every 0.02 In component is a step, each growing 250 nm. Total number of layers is 12. On the p-type InGaAs stress gradient layer 130, grow a second InGaAs solar subcell through epitaxial growth with band gap of 1.1 eV. At first, grow a p-type AlInGaAs rear field layer 141 with growth thickness of 20 nm; then, grow a p-type In_{0.23}Ga_{0.77}As base 142 with growth thickness of 3 μm and doping concentration of 1×10¹⁷ cm⁻³; and grow an n-type In_{0.23}Ga_{0.77}As emitter layer 143 with growth thickness of 150 nm and doping concentration of 2×10¹⁸ cm⁻³; at last, grow an n-type InGaP window layer 144 with growth thickness of 50 nm and doping concentration of 1×10¹⁸ cm⁻³ to form a second InGaAs subcell 140. On the second InGaAs subcell 140, form a 2 μm-thick n-type GaAs cover layer 150 with doping concentration of 5×10¹⁸ cm⁻³ through epitaxial growth so as to form a first epitaxial structure on the Ge substrate. Refer to FIG. 2 for the side section view. In this embodiment, the cover layer 150 can be made of semiconductor materials like InGaP or InGaAs.

Form a second epitaxial structure 200 through epitaxial growth. Clean the n-type GaAs substrate 201 and put it into the MOCVD reaction chamber, where the chamber pressure is 120 mbar. At first, bake the substrate for 10 minutes under 750° C., and lower the temperature to 580° C.; through epitaxial growth, form an n++-GaAs/p++-GaAs tunnel junction 210 and raise the temperature to 650° C.; on the tunnel junction, form a third InGaAsP subcell 220 with band gap of 1.55 eV through epitaxial growth. At first, grow a p-type AlGaAs rear field layer 221 with growth thickness of 20 nm; then, grow a p-type In_{0.26}Ga_{0.74}As_{0.49}P_{0.51} base 222 with growth thickness of 3 μm and doping concentration of 1×10¹⁷ cm⁻³; and grow an n-type In_{0.26}Ga_{0.74}As_{0.49}P_{0.51} emitter layer 223 with growth thickness of 100 nm and doping concentration of 2×10¹⁸ cm⁻³; at last, grow an n-type AlGaInP window layer 224 with growth thickness of 50 nm and doping depth of 1×10¹⁸ cm⁻³. On the third InGaAsP subcell 220, grow an n++-GaInP/p++-AlGaAs tunnel junction 230 through epitaxial growth and lower the temperature to 580° C. At first, grow an n-type GaInP layer with growth thickness of 15 nm and doping concentration of 2×10¹⁹ cm⁻³, and grow a p-type AlGaAs layer with growth thickness of 15 nm and doping concentration of 2×10²⁰ cm⁻³. On the n++-GaInP/p++-AlGaAs tunnel junction 230, grow a fourth Al_{0.1}In_{0.49}Ga_{0.41}InP subcell 240 with band gap of 2.0 eV through epitaxial growth. At first, grow a p-type AlInGaP rear field layer 241 with growth thickness of 20 nm; grow a p-type Al_{0.1}In_{0.49}Ga_{0.41}P base 242 with growth thickness of 600 nm and doping concentration of 6×10¹⁶ cm⁻³; then, grow an n-type Al_{0.1}In_{0.49}Ga_{0.41}P emitter layer 243 with growth thickness of 150 nm and doping concentration of 5×10¹⁸ cm⁻³; at last, grow an n-type AlInP window layer 244 with growth thickness of 50 nm and doping depth of 5×10¹⁸ cm⁻³ so as to fabricate a second epitaxial structure 200 on the GaAs substrate. Refer to FIG. 2 for side section view.

Remove impurities at back surface of the GaAs substrate 201 of the second epitaxial structure 200. On the surface of the second epitaxial structure 200, evaporate a 500 nm SiO₂ thin film to protect the surface layer of the second epitaxial structure 200; then, use the solution with ammonia water: H₂O₅:water=2:3:1 to chemically corrode the GaAs substrate and remove impurities at the back surface of the substrate 201 and expose fresh GaAs monocrystal. Then, clean the second epitaxial structure with deionized water.

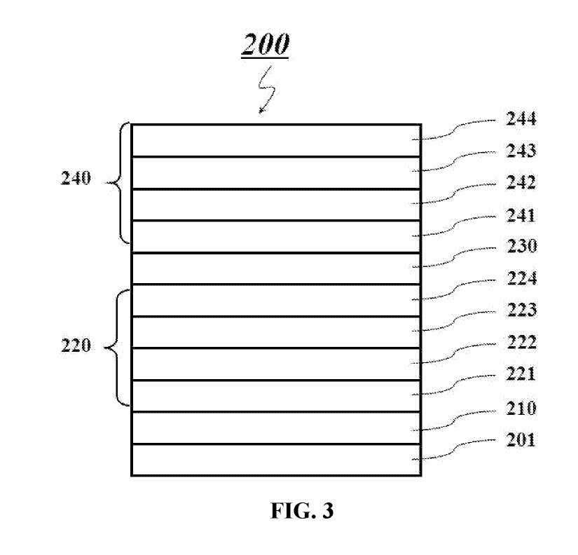

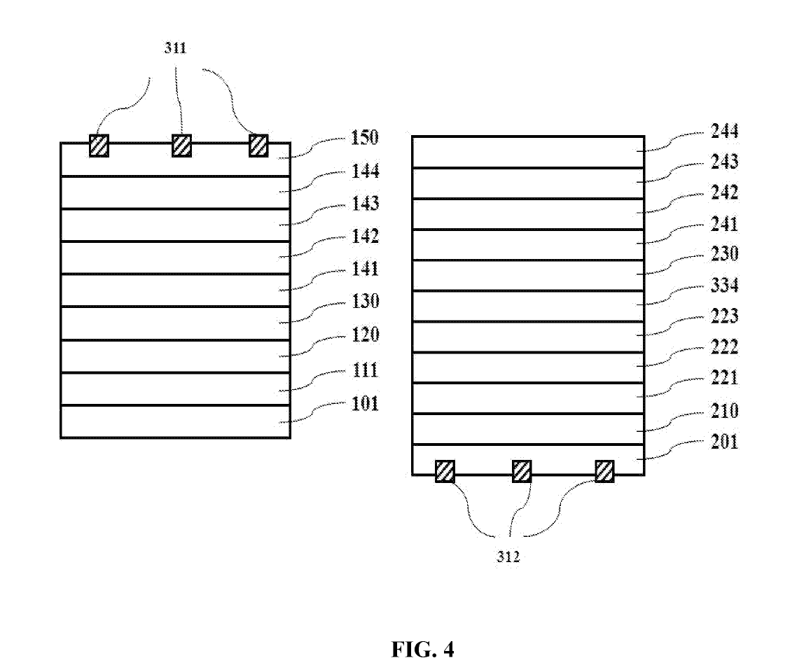

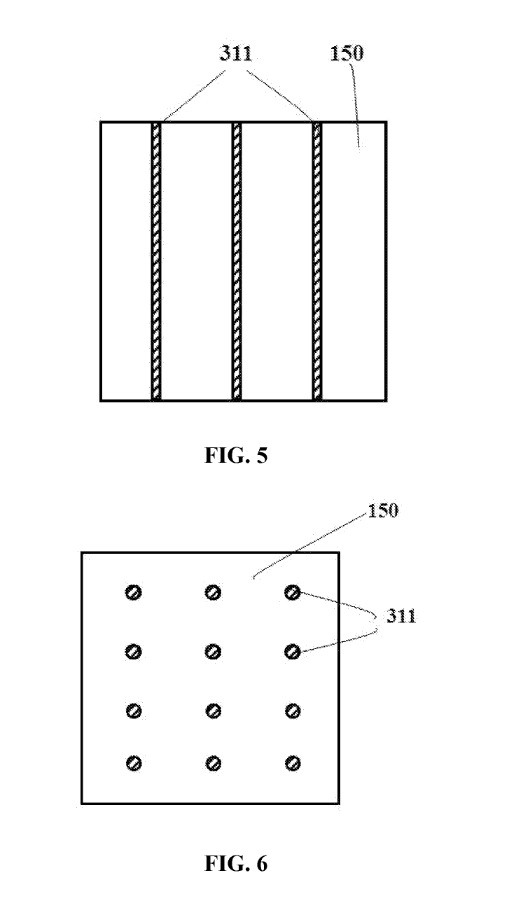

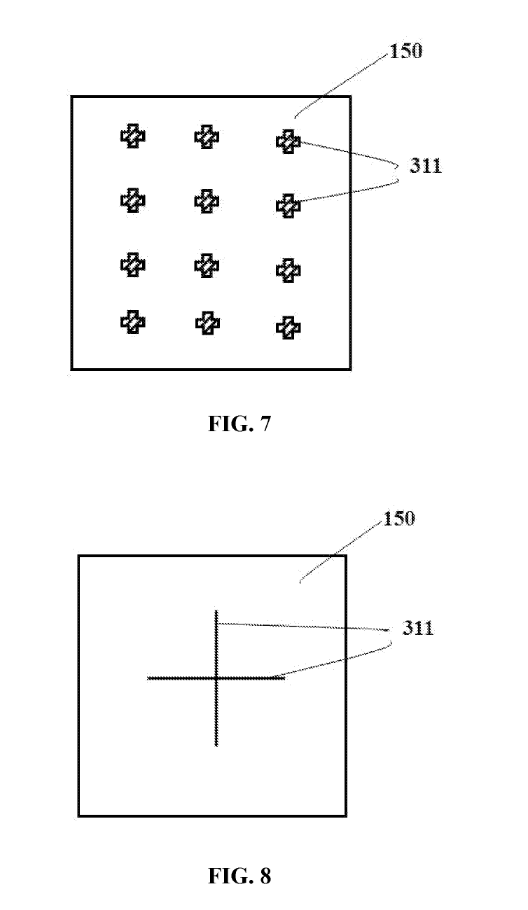

Fabricate a groove on the GaAs cover layer 150 surface of the first epitaxial structure 100 and the back surface of the GaAs substrate 201 of the second epitaxial structure 200, and deposit metal bonding layers 311 and 312. At first, on the GaAs cover layer 150 surface of the first epitaxial structure 100 and the back surface of the GaAs substrate 201 of the second epitaxial structure 200, form etched patterns through photolithographic process, then use solution with citric acid:H₂O₅:water=500 g:500 ml:100 ml to corrode the GaAs not protected by the photoresist so as to form a groove on the GaAs cover layer surface of the first epitaxial structure and the back surface of the GaAs substrate of the second epitaxial structure with etching depth of 200 nm. Deposit an AuGe (200 nm)/Au (100 nm) layer inside the groove as a metal bonding layer. Strip the photoresist and the metal layer above to expose the GaAs surface with hydrophilic property. Finally, form metal bonding layers 311 and 312 in the groove of the GaAs cover layer surface of the first epitaxial structure 100 and the back surface of the GaAs substrate 201 of the second epitaxial structure 200. Refer to FIG. 3 for the side section view. Referring to FIGS. 5-8, patterns of the metal bonding layer can present a series of parallel stripe distribution or evenly-arranged circular and cross distribution, or is only composed of two cross grooves in the center region, where the metal bonding layer 311 (312) takes up 1‰-10% in the epitaxial structure, and preferably 6%.

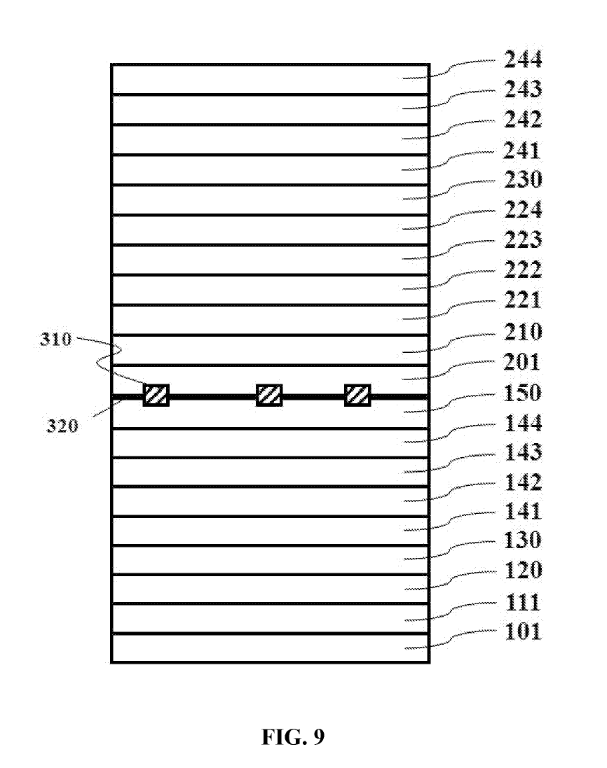

Bond the first epitaxial structure 100 and the second epitaxial structure 200. Bond the GaAs cover layer 150 of the first epitaxial structure to the back surface of the GaAs substrate 201 of the second epitaxial structure. At the same time, ensure that metal bonding layers 311 and 312 are aligned to each other and bonded for 1 hour under 450° C. nitrogen environment to finally fabricate an AlInGaP/InGaAsP/InGaAs/Ge four-junction solar cell. Refer to FIG. 9 for the side section view.

Different from the four-junction cell fabricated through flip-chip epitaxial technology, this embodiment can obtain high quality four-junction subcells with guaranteed performance only with normal epitaxial technology; in the AlGaInP/AlInGaAs (or InGaAsP)/InGaAs/Ge four-junction cell of this embodiment, the band gap combination is 2.0 eV/1.55 eV/1.1 eV/0.67 eV. High open-circuit voltage (>4.1 V under 1,000×) eliminates the influence from current limit of the first and second junction subcells on the fourth subcell. Besides, dual bonding process is used between the bonding metals and between the semiconductors, thus removing the problems of insufficient bonding strength in direct semiconductor bonding and gap problem in alignment bonding.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A four-junction solar cell, comprising:
a first epitaxial structure; and
a second epitaxial structure over the first epitaxial structure, wherein:
the first epitaxial structure comprises:
a first substrate, a first subcell, a second subcell and a cover layer stacked from bottom up, and
the second epitaxial structure comprises:
a second substrate, a third subcell and a fourth subcell stacked from bottom up;
the cover layer surface of the first epitaxial structure and the second substrate back surface of the second epitaxial structure each have a groove deposited with a metal bonding layer;
the cover layer surface of the first epitaxial structure and the second substrate back surface of the second epitaxial structure are bonded, and the bonding surface is divided into a groove region and another region, wherein the groove region is where the groove is located and a bonding interface between the metal bonding layers, and the other region is a bonding interface between the cover layer and the second substrate.

2. The four-junction solar cell of claim 1, wherein: the first substrate is a Ge substrate, and the second subcell comprises an InGaAs emitter layer and a base.

3. The four-junction solar cell of claim 1, wherein: the cover layer of the first epitaxial structure comprises at least one of GaAs, InGaP, or InGaAs.

4. The four-junction solar cell of claim 1, wherein: the second substrate is a GaAs substrate; the third subcell comprises an InGaAsP or AlInGaAs emitter layer and a base; and the fourth subcell comprises an AlInGaP emitter layer and a base.

5. The four-junction solar cell of claim 1, wherein: the metal bonding layer is made of AuGe alloy, AuSn alloy, AuBe alloy or Au.

6. The four-junction solar cell of claim 1, wherein: the metal bonding layer takes up 1‰-10% of the first and the second epitaxial structures.

7. A fabrication method of a high-efficiency four-junction solar cell, the method comprising:
forming a first epitaxial structure and a second epitaxial structure through epitaxial growth;
forming a first epitaxial structure on a first substrate through a forward epitaxial growth, and forming a second epitaxial structure over the second substrate, wherein:
the first epitaxial structure comprises a first subcell, a second subcell, and a cover layer formed over the first substrate;
the second epitaxial structure comprises a third subcell and a fourth subcell over the second substrate;
forming a groove and a metal bonding layer;
forming a groove on the cover layer surface of the first epitaxial structure and the substrate back surface of the second epitaxial structure, and depositing a metal bonding layer in the groove;
bonding the first epitaxial structure and the second epitaxial structure;
bonding the cover layer surface of the first epitaxial structure and the substrate back surface of the second epitaxial structure, ensuring that the metal bonding layers are aligned to each other to realize dual bonding between the metal bonding layers and between the semiconductors through a high-temperature and a high-pressure treatment, thereby forming the high-efficiency four-junction solar cell;
wherein the high-efficiency four-junction solar cell comprises:
the first epitaxial structure; and
the second epitaxial structure over the first epitaxial structure, wherein:
the first epitaxial structure comprises:
the first substrate, the first subcell, the second subcell and the cover layer stacked from bottom up, and
the second epitaxial structure comprises:
the second substrate, the third subcell and the fourth subcell stacked from bottom up;
the cover layer surface of the first epitaxial structure and the second substrate back surface of the second epitaxial structure each have the groove deposited with the metal bonding layer;
the cover layer surface of the first epitaxial structure and the second substrate back surface of the second epitaxial structure are bonded, and the bonding surface is divided into a groove region and another region, wherein the groove region is where the groove is located and a bonding interface between the metal bonding layers, and the other region is a bonding interface between the cover layer and the second substrate.

8. The method of claim 7, wherein: the first substrate is a Ge substrate, and the second subcell comprises an InGaAs emitter layer and a base.

9. The method of claim 7, wherein: the cover layer of the first epitaxial structure comprises at least one of GaAs, InGaP, or InGaAs.

10. The method of claim 7, wherein: the second substrate is a GaAs substrate; the third subcell comprises an InGaAsP or AlInGaAs emitter layer and a base; and the fourth subcell comprises an AlInGaP emitter layer and a base.

11. The method of claim 7, wherein: a relationship between a height of the metal bonding layer H and a depth of the groove D is: 0<H-D<300 nm.

12. The method of claim 7, wherein: the metal bonding layer comprises at least one of AuGe alloy, AuSn alloy, AuBe alloy, or Au.

13. The method of claim 7, wherein: the metal bonding layer takes up 1‰-10% of the first and the second epitaxial structures.

14. A solar system comprising a plurality of four-junction solar cells, each solar cell comprising:
a first epitaxial structure; and
a second epitaxial structure over the first epitaxial structure, wherein:
the first epitaxial structure comprises:
a first substrate, a first subcell, a second subcell and a cover layer stacked from bottom up, and
the second epitaxial structure comprises:
a second substrate, a third subcell and a fourth subcell stacked from bottom up;
the cover layer surface of the first epitaxial structure and the second substrate back surface of the second epitaxial structure each have a groove deposited with a metal bonding layer;
the cover layer surface of the first epitaxial structure and the second substrate back surface of the second epitaxial structure are bonded, and the bonding surface is divided into a groove region and another region, wherein the groove region is where the groove is located and a bonding interface between the metal bonding layers, and the other region is a bonding interface between the cover layer and the second substrate.

15. The system of claim 14, wherein: the first substrate is a Ge substrate, and the second subcell comprises an InGaAs emitter layer and a base.

16. The system of claim 14, wherein: the cover layer of the first epitaxial structure comprises at least one of GaAs, InGaP, or InGaAs.

17. The system of claim 14, wherein: the second substrate is a GaAs substrate; the third subcell comprises an InGaAsP or AlInGaAs emitter layer and a base; and the fourth subcell comprises an AlInGaP emitter layer and a base.

18. The system of claim 14, wherein: the metal bonding layer is made of AuGe alloy, AuSn alloy, AuBe alloy or Au.

19. The system of claim 14, wherein: the metal bonding layer takes up 1‰-10% of the first and the second epitaxial structures.
